(19) United States
(12) Patent Application Publication
(10) Pub. No.: US 2026/0052944 A1
(43) Pub. Date: Feb. 19, 2026

(54) BONDING APPARATUS AND BONDING METHOD

(71) Applicant: DISCO CORPORATION, Tokyo (JP)

(72) Inventors: Ryosuke KUROSAWA, Tokyo (JP); Takashi MORI, Tokyo (JP); Yoshinori KAKINUMA, Tokyo (JP)

(21) Appl. No.: 19/288,059

(22) Filed: Aug. 1, 2025

(30) Foreign Application Priority Data
Aug. 14, 2024 (JP) 2024-135243

(51) Int. Cl. H01L 21/68; H01L 21/18; H01L 21/66; H01L 21/67

(52) U.S. Cl. CPC H01L 21/681; H01L 21/185; H01L 21/67092; H01L 21/67259; H01L 22/20

(57) ABSTRACT

A bonding apparatus includes: a first holder configured to hold a first substrate; a second holder disposed to face the first holder and configured to hold a second substrate to be bonded to the first substrate; an imaging unit including a first portion including a first objective lens that captures an image of a first mark formed on the first substrate held by the first holder, and a second portion including a second objective lens that captures an image of a second mark formed on the second substrate held by the second holder; and a mover configured to relatively move the imaging unit, first holder, and second holder in a region between the first holder and the second holder. In the imaging unit, an optical axis of the first objective lens and an optical axis of the second objective lens are not on a same straight line.

### CROSS-REFERENCE TO RELATED APPLICATIONS

This application is based on and claims priority under 35 USC 119 from Japanese Patent Application No. 2024-135243 filed on Aug. 14, 2024, the contents of which are incorporated herein by reference.

### TECHNICAL FIELD

The present disclosure relates to a bonding apparatus and a bonding method for bonding substrates together.

### BACKGROUND

The related art discloses a technique for bonding substrates such as semiconductor wafers or glass substrates together.

For example, Japanese Patent Application Laid-Open Publication No. 2016-4799A discloses a method for forming a wafer in which a silicon substrate and a support member are bonded together via an oxide film by room-temperature bonding.

In such bonding of substrates via an oxide film, once the substrates are bonded together, it is difficult to redo the bonding thereafter, and thus it is desired to prevent misalignment between the substrates when the substrates are bonded together.

The present disclosure provides a bonding apparatus and a bonding method that can prevent misalignment between substrates when the substrates are bonded together.

### SUMMARY

A first aspect of the present disclosure relates to a bonding apparatus for bonding a first substrate and a second substrate. The bonding includes: a first holding portion configured to hold the first substrate; a second holding portion disposed to face the first holding portion and configured to hold the second substrate to be bonded to the first substrate; an imaging unit including a first imaging portion including a first objective lens that captures an image of a first alignment mark formed on the first substrate held by the first holding portion, and a second imaging portion including a second objective lens that captures an image of a second alignment mark formed on the second substrate held by the second holding portion; and a moving unit configured to relatively move the imaging unit, the first holding portion, and the second holding portion in a region between the first holding portion and the second holding portion. In the imaging unit, an optical axis of the first objective lens and an optical axis of the second objective lens are not on a same straight line.

A second aspect of the present disclosure relates to a bonding method for bonding a first substrate and a second substrate. The bonding method includes: first holding the first substrate by a first holding portion; second holding the second substrate by a second holding portion disposed to face the first holding portion; first positioning an imaging unit in a region between the first holding portion and the second holding portion in order to capture an image of a first alignment mark with a first objective lens, the imaging unit including a first imaging portion including the first objective lens that captures an image of the first alignment mark formed on the first substrate held by the first holding portion, and a second imaging portion including a second objective lens that captures an image of a second alignment mark formed on the second substrate held by the second holding portion and that has an optical axis not disposed on a same straight line as an optical axis of the first objective lens; first capturing an image of the first alignment mark using the imaging unit after the first positioning; second positioning the imaging unit in the region between the first holding portion and the second holding portion in order to capture an image of the second alignment mark with the second objective lens; second capturing an image of the second alignment mark using the imaging unit after the second positioning; retracting the imaging unit located in the region between the first holding portion and the second holding portion; and bonding the first substrate and the second substrate after the retracting.

According to the present disclosure, it is possible to prevent misalignment between substrates when the substrates are bonded together.

### BRIEF DESCRIPTION OF DRAWINGS

Exemplary embodiments of the present disclosure will be described in detail based on the following figures, wherein

FIG. 1A is a perspective view illustrating an example of a first substrate W1 and a second substrate W2;

FIG. 1B is a perspective view illustrating an example of a first substrate W1 and a second substrate W2;

FIG. 2 is a diagram for explaining bonding of the first substrate W1 and the second substrate W2;

FIG. 3 is a perspective view illustrating an example of a bonding apparatus 1;

FIG. 4 is a diagram for explaining an example of a bonding unit 100;

FIG. 5A is a diagram for explaining a first imaging portion 121 and a second imaging portion 122 in an embodiment;

FIG. 5B is a diagram for explaining a first imaging portion 121 and a second imaging portion 122 in an embodiment;

FIG. 6 is a flowchart illustrating an example of a process of a bonding method.

FIG. 7A is a diagram for explaining a first holding step S10;

FIG. 7B is a diagram for explaining a second holding step S11;

FIG. 8 is a diagram for explaining a first positioning step S12 and a second positioning step S14;

FIG. 9 is a diagram for explaining each imaging step;

FIG. 10 is a diagram for explaining a retraction step S20;

FIG. 11 is a diagram for explaining a bonding step S21;

FIG. 12 is a perspective view illustrating an example of a bonded substrate W3;

FIG. 13A is a diagram for explaining a comparative example of the first imaging portion and the second imaging portion; and

FIG. 13B is a diagram for explaining a comparative example of the first imaging portion and the second imaging portion.

### DESCRIPTION OF EMBODIMENTS

Hereinafter, a bonding apparatus and a bonding method for substrates according to an embodiment of the present disclosure will be described with reference to the drawings.

First, before describing a bonding apparatus 1 and the bonding method, a substrate W used in the bonding apparatus 1 and the bonding method will be described. The substrate W is, for example, a wafer made of a material such as silicon (Si), silicon carbide (SiC), gallium nitride (GaN), gallium arsenide (GaAs), or other semiconductor materials.

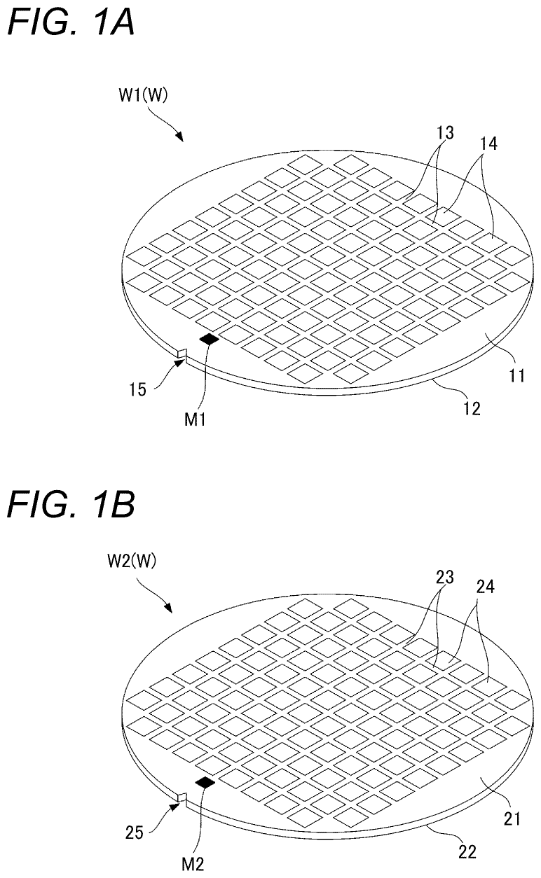

FIGS. 1A and 1B are perspective views illustrating an example of the substrate W. FIG. 1A illustrates a first substrate W1 which is an example of one of the substrates to be bonded, and FIG. 1B illustrates a second substrate W2 which is an example of the other of the substrates to be bonded.

In the following description, the first substrate is denoted by a reference numeral “W1”, the second substrate is denoted by a reference numeral “W2”, the bonded substrate formed by bonding the first substrate W1 and the second substrate W2 is denoted by a reference numeral “W3”, and the first substrate W1, the second substrate W2, and the bonded substrate W3 are simply denoted by a reference numeral “W” when the first substrate W1, the second substrate W2, and the bonded substrate W3 are not distinguished from one another.

The first substrate W1 has a front surface 11 and a back surface 12 substantially parallel to each other. On the front surface 11 of the first substrate W1, as illustrated in FIG. 1A, a plurality of intersecting streets 13 are set as planned dividing lines, and a plurality of regions partitioned by the planned dividing lines are formed in a grid pattern. A device 14 such as an integrated circuit (IC), a large scale integrated circuit (LSI), or a micro electro mechanical system (MEMS) is formed in each of the partitioned regions.

A first alignment mark M1 is formed on the first substrate W1. The first alignment mark M1 serves as a mark for alignment when the first substrate W1 and the second substrate W2 are bonded, and is formed on, for example, an outer peripheral portion of the first substrate W1 where no device 14 is formed. A notch indicating a crystal orientation of the first substrate W1 is denoted by a reference numeral 15.

The second substrate W2 may have the same configuration as the first substrate W1. That is, the second substrate W2 also has a front surface 21 and a back surface 22 substantially parallel to each other. On the front surface 21 of the second substrate W2, as illustrated in FIG. 1B, a plurality of intersecting streets 23 are set as planned dividing lines, and a plurality of regions partitioned by the planned dividing lines are formed in a grid pattern. A device 24 such as an IC, an LSI, or a MEMS is formed in each of the partitioned regions. A notch indicating a crystal orientation of the second substrate W2 is denoted by a reference numeral 25.

A second alignment mark M2 is formed on the second substrate W2. The second alignment mark M2 serves as a mark for alignment when the second substrate W2 and the first substrate W1 are bonded together, and is formed on, for example, an outer peripheral portion of the second substrate W2 where no device 24 is formed, and is formed at the same position as the first alignment mark M1. In the following description, when the first alignment mark M1 and the second alignment mark M2 are not distinguished from each other, the first alignment mark M1 and the second alignment mark M2 are simply referred to as an “alignment mark M”.

On each of the front surface 11 of the first substrate W1 and the front surface 21 of the second substrate W2, a laminated body including various patterned thin films such as a conductive film functioning as an electrode, a wiring, a terminal, or the like and an insulating film functioning as an interlayer insulating film (none of which is illustrated) is formed.

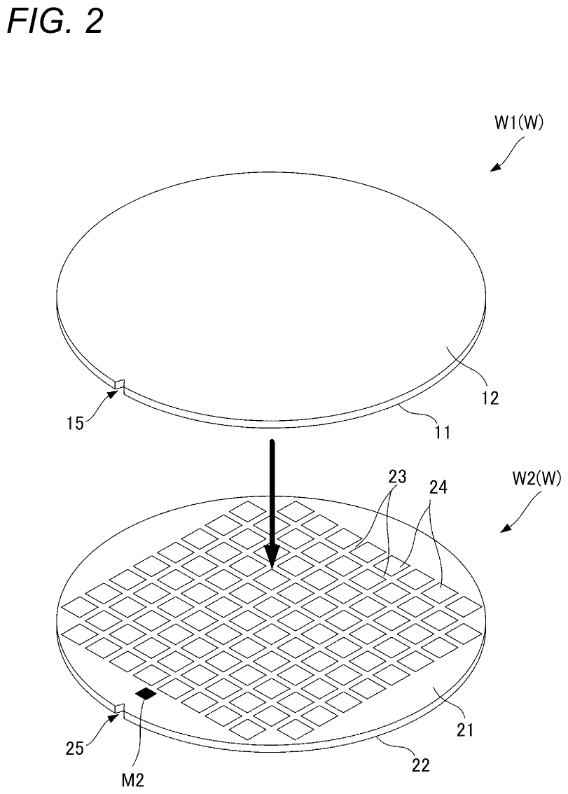

The front surface 11 of the first substrate W1 and the front surface 21 of the second substrate W2 configured as described above face each other, and the substrates are bonded together by the bonding apparatus 1 (see FIG. 2). As a result, the bonded substrate W3 (see FIG. 12) in which the first substrate W1 and the second substrate W2 are bonded together is formed.

The device 14 of the first substrate W1 and the device 24 of the second substrate W2 each includes an electrode pad and a through electrode connected to the electrode pad, and the through electrode enables connection of electrodes when the substrates are bonded together. That is, the first substrate W1 and the second substrate W2 are substrates in which the device has a through electrode (TSV: Through Silicon Via).

The bonding of the first substrate W1 and the second substrate W2 is performed by the bonding apparatus 1, but once the substrates are bonded together, it is difficult to redo the bonding thereafter, and thus it is preferable to prevent misalignment between the substrates facing each other when the substrates are bonded together. Therefore, in the embodiment, the bonding apparatus 1 that can prevent such misalignment between the substrates is configured.

### Bonding Apparatus

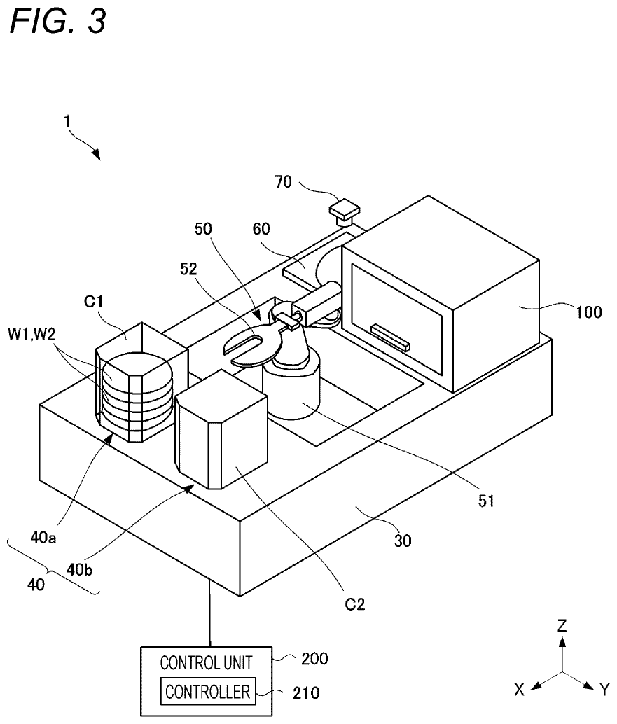

FIG. 3 schematically illustrates an example of the bonding apparatus 1. In the following description, an X-axis direction is a direction on a horizontal plane. A Y-axis direction is a direction orthogonal to the X-axis direction on the horizontal plane. A Z-axis direction is a direction orthogonal to the X-axis direction and the Y-axis direction.

The bonding apparatus 1 includes, as main components, a base 30, a cassette accommodation portion 40, a carrying unit 50, a temporary placement table 60, a bonding unit 100, and a control unit 200.

The cassette accommodation portion 40 is provided on one end side in the X-axis direction on the base 30, and includes two accommodation spaces, a first accommodation space 40a and a second accommodation space 40b, which are aligned in the Y-axis direction. For example, a cassette C1 that accommodates the first substrate W1 and the second substrate W2 before being bonded is placed in the first accommodation space 40a. For example, a cassette C2 that accommodates the bonded substrate W3 after bonding is placed in the second accommodation space 40b. Each of the cassette C1 and the cassette C2 can accommodate a plurality of substrates W.

The carrying unit 50 is provided adjacent to the cassette accommodation portion 40, and carries the substrate W into and out of the cassettes C1 and C2. The carrying unit 50 includes a pedestal 51 and a rotatable arm 52 supported on the pedestal 51. For example, the pedestal 51 is movable in the X-axis direction and the Y-axis direction. The direction in which the pedestal 51 can move may be any direction as long as the substrate W can be carried into and out by the movement of the pedestal 51 and the operation of the arm 52. When the substrate W can be carried into and out by the operation of the arm 52 alone, the pedestal 51 may be configured not to move. In the embodiment, for example, the carrying unit 50 can be moved in the X-axis direction and the Y-axis direction by a known movement mechanism (not illustrated) including a guide rail, a ball screw, a pulse motor, and the like.

The carrying unit 50 carries the substrate W between the cassette accommodation portion 40, the temporary placement table 60, and the bonding unit 100 by the movement of the pedestal 51 and the operation of the arm 52. Specifically, the carrying unit 50 carries out the first substrate W1 and the second substrate W2 before being bonded from the cassette C1 and carries the first substrate W1 and the second substrate W2 into the temporary placement table 60, and carries out the first substrate W1 and the second substrate W2 from the temporary placement table 60 and carries the first substrate W1 and the second substrate W2 into the bonding unit 100. Alternatively, the first substrate W1 and the second substrate W2 before being bonded are carried out from the cassette C1 and carried into the bonding unit 100. The carrying unit 50 carries out the bonded substrate W3 produced by the bonding unit 100 from the bonding unit 100 and carries the bonded substrate W3 into the cassette C2 in the second accommodation space 40b.

The temporary placement table 60 holds the carried first substrate W1 and second substrate W2 under suction by operating a suction source (not illustrated). The temporary placement table 60 is provided with an imaging mechanism 70 that captures an image of the carried substrate W. The imaging mechanism 70 can execute a process corresponding to a pre-alignment step S16 to be described later, based on the imaged substrate W and the alignment mark M formed on the substrate W. The process corresponding to the pre-alignment step S16 is not necessarily executed on the temporary placement table 60, and may be executed on the temporary placement table 60 or in the bonding unit 100 to be described later. In the embodiment, since an example in which the pre-alignment step S16 is executed in the bonding unit 100 will be described, a detailed description of the process that can be executed on the temporary placement table 60 will be omitted.

The bonding unit 100 includes a chamber 102 capable of forming a sealed processing space therein, and reduces the pressure in the chamber 102 after the first substrate W1 and the second substrate W2 carried by the carrying unit 50 are accommodated in the chamber 102. Then, the bonding unit 100 bonds the first substrate W1 and the second substrate W2 in the chamber 102 whose pressure is reduced.

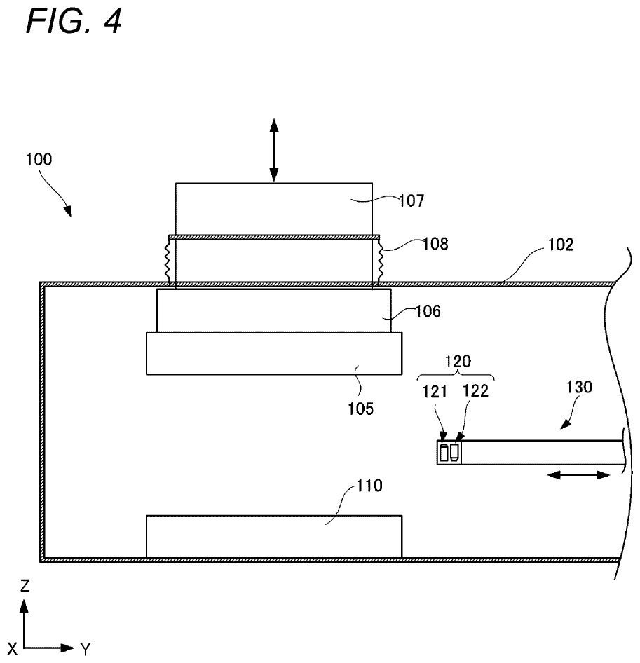

FIG. 4 is a diagram schematically illustrating an example of the bonding unit 100. Specifically, the bonding unit 100 includes a first holding portion 105 that holds the first substrate W1, a second holding portion 110 that holds the second substrate W2, an imaging unit 120 that captures an image of the first alignment mark M1 provided on the first substrate W1 and the second alignment mark M2 provided on the second substrate W2, and a moving unit 130 that moves the imaging unit 120.

The first holding portion 105 is a holding portion that holds the first substrate W1 under suction, is provided so as to face the second holding portion 110, and is supported so as to be movable up and down in a vertical direction (Z-axis direction) with a holding surface facing downward. The first substrate W1 is held by the first holding portion 105 with a bonding surface (that is, the front surface 11) with the second substrate W2 facing downward. A lower surface of the first holding portion 105 is the holding surface made of, for example, porous ceramics or the like, and holds the first substrate W1 under suction by operating a suction source (not illustrated).

An adjustment unit 106 for adjusting a horizontal position of the first holding portion 105 is provided above the first holding portion 105. The adjustment unit 106 can move the first holding portion 105 in the X-axis direction or the Y-axis direction. The adjustment unit 106 can rotate the first holding portion 105 around a Z-axis.

Further, a through hole penetrating the chamber 102 in the Z-axis direction is formed above the adjustment unit 106, and a shaft 107 is inserted into the through hole. The shaft 107 can be lifted and lowered in the vertical direction together with the first holding portion 105 and the adjustment unit 106 by, for example, a lifting mechanism (not illustrated). When the shaft 107 moves up and down, the first holding portion 105 and the second holding portion 110 approach or separate from each other. A tubular bellows joint 108 is provided around the through hole so as to surround the through hole.

The second holding portion 110 is a holding portion that holds the second substrate W2 under suction, is provided so as to face the first holding portion 105, and is supported on a lower side of the chamber 102 with a bonding surface (that is, the front surface 21) of the second substrate W2 with the first substrate W1 facing upward.

In the embodiment, the adjustment unit 106 described above is provided on the first holding portion 105 side, but the adjustment unit 106 may be provided on the second holding portion 110 side. In the embodiment, the first holding portion 105 and the second holding portion 110 approach or separate from each other when the first holding portion 105 moves up and down together with the shaft 107, but the second holding portion 110 may move up and down to approach or separate from the first holding portion.

The imaging unit 120 includes, for example, a camera having an imaging sensor such as a CCD (Charged-Coupled Devices) sensor or a CMOS (Complementary Metal-Oxid e-Semiconductor) sensor. The imaging unit 120 captures images of the first alignment mark M1 provided on the first substrate W1 and the second alignment mark M2 provided on the second substrate W2. The imaging unit 120 includes a first imaging portion 121 that captures an image of the first alignment mark M1 and a second imaging portion 122 that captures an image of the second alignment mark M2.

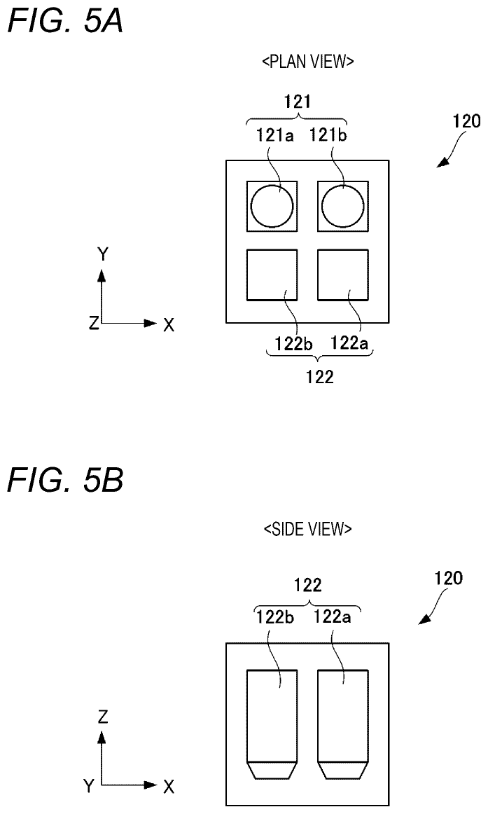

As illustrated in FIG. 5A, the first imaging portion 121 includes, as lenses for capturing an image of the first alignment mark M1 formed on the first substrate W1, a first wide-area objective lens 121a which is a wide-area macro lens, and a first local objective lens 121b which is a micro lens having a magnification higher than that of the first wide-area objective lens 121a and capable of capturing images with relatively high resolution.

By using the first wide-area objective lens 121a, the first imaging portion 121 can capture an image of the first substrate W1 including the first alignment mark M1 in a relatively wide range. By using the first local objective lens 121b, the first imaging portion 121 can capture an image of the first alignment mark M1 of the first substrate W1 with higher resolution than in the case of using the first wide-area objective lens 121a. The first imaging portion 121 can focus the first wide-area objective lens 121a and the first local objective lens 121b on the first substrate W1.

Similarly, as illustrated in FIG. 5A, the second imaging unit 122 includes, as lenses for capturing an image of the second alignment mark M2 formed on the second substrate W2, a second wide-area objective lens 122a which is a wide-area macro lens, and a second local objective lens 122b which is a micro lens having a magnification higher than that of the second wide-area objective lens 122a and capable of capturing images with relatively high resolution.

By using the second wide-area objective lens 122a, the second imaging unit 122 can capture an image of the second substrate W2 including the second alignment mark M2 in a relatively wide range. By using the second local objective lens 122b, the second imaging unit 122 can capture an image of the second alignment mark M2 of the second substrate W2 with higher resolution than in the case of using the second wide-area objective lens 122a. The second imaging unit 122 can focus the second wide-area objective lens 122a and the second local objective lens 122b on the second substrate W2.

The first imaging portion 121 is attached to the moving unit 130 to be described later with the first wide-area objective lens 121a and the first local objective lens 121b facing upward. The second imaging unit 122 is attached to the moving unit 130 to be described later with the second wide-area objective lens 122a and the second local objective lens 122b facing downward.

The arrangement of each lens (hereinafter, also collectively referred to as “lenses”), that is, the first wide-area objective lens 121a, the first local objective lens 121b, the second wide-area objective lens 122a, and the second local objective lens 122b attached to the moving unit 130 is, for example, the arrangement illustrated in FIGS. 5A and 5B in the embodiment. FIG. 5A illustrates the arrangement of the lenses in a plan view, and FIG. 5B illustrates the arrangement of the lenses in a side view.

The lenses are attached to the moving unit 130 so as to capture an image of the first substrate W1 positioned above the lenses or to capture an image of the second substrate W2 positioned below the lenses, and an optical axis of each lens extends in the vertical direction. In the embodiment, as illustrated in FIGS. 5A and 5B, the lenses are disposed in parallel in a planar region in the X-axis direction and the Y-axis direction orthogonal to the X-axis direction.

More specifically, since the first wide-area objective lens 121a and the second wide-area objective lens 122a are disposed in parallel, the optical axis of the first wide-area objective lens 121a and the optical axis of the second wide-area objective lens 122a are not on the same straight line. Similarly, since the first local objective lens 121b and the second local objective lens 122b are disposed in parallel, the optical axis of the first local objective lens 121b and the optical axis of the second local objective lens 122b are not on the same straight line. The optical axes of the four lenses do not overlap on the same straight line.

As an example, in the embodiment, as illustrated in FIG. 5A, the first wide-area objective lens 121a, the second wide-area objective lens 122a, the first local objective lens 121b, and the second local objective lens 122b are disposed in the shape of field character grid in a plan view. That is, the lenses are disposed in a “2×2” grid.

When such an arrangement is defined in relation to a moving direction of the moving unit 130 to be described later, the arrangement can also be defined as follows. For example, the first wide-area objective lens 121a, the second wide-area objective lens 122a, the first local objective lens 121b, and the second local objective lens 122b are disposed in an overlapping manner such that two objective lenses are visible when viewed from one moving direction (for example, Y-axis direction) of the moving unit 130, and are disposed in an overlapping manner such that two objective lenses are visible when viewed from a direction (for example, X-axis direction) orthogonal to the moving direction on the same plane. That is, it can be said that the lenses are disposed at four locations at equal intervals in a horizontal plane in the X-axis direction and the Y-axis direction.

In the example illustrated in FIG. 5A, the lenses are disposed in the order of the first wide-area objective lens 121a, the first local objective lens 121b, the second wide-area objective lens 122a, and the second local objective lens 122b clockwise from the upper left, but the arrangement may be appropriately changed.

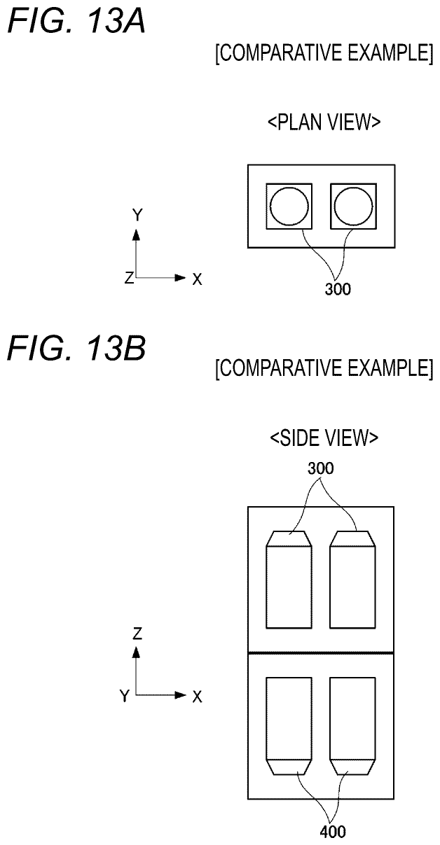

As described above, since the first wide-area objective lens 121a, the second wide-area objective lens 122a, the first local objective lens 121b, and the second local objective lens 122b are disposed in parallel on the same plane, the optical axes are not on the same straight line in the vertical direction. In other words, the lenses do not overlap each other in the vertical direction. Thus, for example, as illustrated in a comparative example of FIGS. 13A and 13B, as compared with a case where an optical axis of an objective lens 300 facing upward for capturing an image of the first substrate W1 and an optical axis of an objective lens 400 facing downward for capturing an image of the second substrate W2 are disposed on the same straight line in the vertical direction, a distance between the first holding portion 105 and the second holding portion 110 facing each other can be shortened, and as a result, a distance between the first substrate W1 and the second substrate W2 can be shortened. Since the distance between the substrates can be shortened as described above, it is possible to prevent misalignment between the first substrate W1 and the second substrate W2 when the substrates are bonded together. FIG. 13A is an example when the objective lens 300 and the objective lens 400 are in a plan view, and FIG. 13B is an example when the objective lens 300 and the objective lens 400 are in a side view.

Returning to FIG. 4, the moving unit 130 will be described. The moving unit 130 moves the imaging unit 120 in a planar region between the first holding portion 105 and the second holding portion 110, that is, along the X-axis direction and the Y-axis direction. The moving unit 130 may have various configurations, and may be, for example, a known ball screw type moving unit. The moving unit 130 may include a guide rail.

The first imaging portion 121 and the second imaging portion 122 described above are attached to one end of the moving unit 130, that is, the moving unit 130 can integrally move the first imaging portion 121 and the second imaging portion 122. For example, the moving unit 130 moves along the Y-axis direction to move the imaging unit 120 between an imaging position between the first holding portion 105 and the second holding portion 110 and a retracted position which is a position deviated from the imaging position between the first holding portion 105 and the second holding portion 110.

As described above, since the moving unit 130 can move in the X-axis direction and the Y-axis direction, for example, even if the first alignment mark M1 or the second alignment mark M2 is formed on an outer peripheral side of the substrate W as in the embodiment, or even if the first alignment mark M1 or the second alignment mark M2 is formed on an inner peripheral side of the substrate W, it is possible to capture an image of the alignment mark M by moving the moving unit 130 to a position where the alignment mark M is formed.

Since the moving unit 130 can integrally move the first imaging portion 121 and the second imaging portion 122, the moving unit 130 can move to the imaging position and capture an image simultaneously in the imaging of the first alignment mark M1 and the second alignment mark M2.

An exhaust pipe for suctioning air from the chamber 102 is connected to the chamber 102, and the exhaust pipe is connected to an exhaust device such as a vacuum pump (both not illustrated).

The control unit 200 controls each of the above-described components of the bonding apparatus 1 to cause the bonding apparatus 1 to execute various processes and the like. The control unit 200 is a computer including a controller 210 that performs various calculations, a storage unit having a storage medium, and an input and output interface (all not illustrated) that controls input and output of data between the inside and outside of the control unit 200. The controller 210 includes, for example, a microprocessor such as a central processing unit (CPU). The storage unit includes a memory such as a hard disk drive (HDD), a read only memory (ROM), or a random access memory (RAM). The controller 210 performs various calculations based on a predetermined program stored in the storage unit. The controller 210 outputs, according to a calculation result, various control signals to the components described above via the input and output interface, and controls the bonding apparatus 1.

The controller 210 executes various programs stored in the storage unit. As an example, the controller 210 executes a program for preventing misalignment when bonding substrates together. Specific processes will be described in the following bonding method.

### Bonding Method

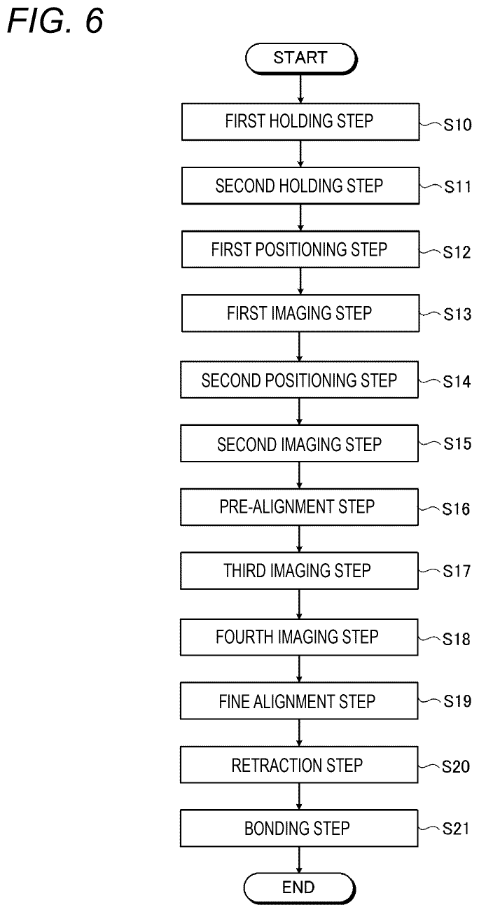

Next, a substrate bonding method according to the embodiment will be described. FIG. 6 is a flowchart illustrating an example of the bonding method. The bonding method includes, as processes, a first holding step S10, a second holding step S11, a first positioning step S12, a first imaging step S13, a second positioning step S14, a second imaging step S15, the pre-alignment step S16, a third imaging step S17, a fourth imaging step S18, a fine alignment step S19, a retraction step S20, and a bonding step S21. The process of each step is executed by the controller 210.

In the bonding method according to the embodiment, before executing the first holding step S10, the controller 210 performs a plasma activation process of supplying a plasma gas to the front surface 11 of the first substrate W1 and the front surface 21 of the second substrate W2 serving as bonding surfaces to activate the bonding surfaces so as to bond the first substrate W1 and the second substrate W2. By executing such plasma activation process, surface impurities such as organic substances adsorbed on the front surfaces of the first substrate W1 and the second substrate W2 are removed, and clean surfaces are exposed. Further, hydroxyl groups (OH groups) are bonded to the exposed clean front surfaces. That is, OH groups are formed on the front surfaces of the first substrate W1 and the second substrate W2 activated by the plasma activation process. Then, the first substrate W1 and the second substrate W2 subjected to such plasma activation process are accommodated in the cassette C1 in the first accommodation space 40a.

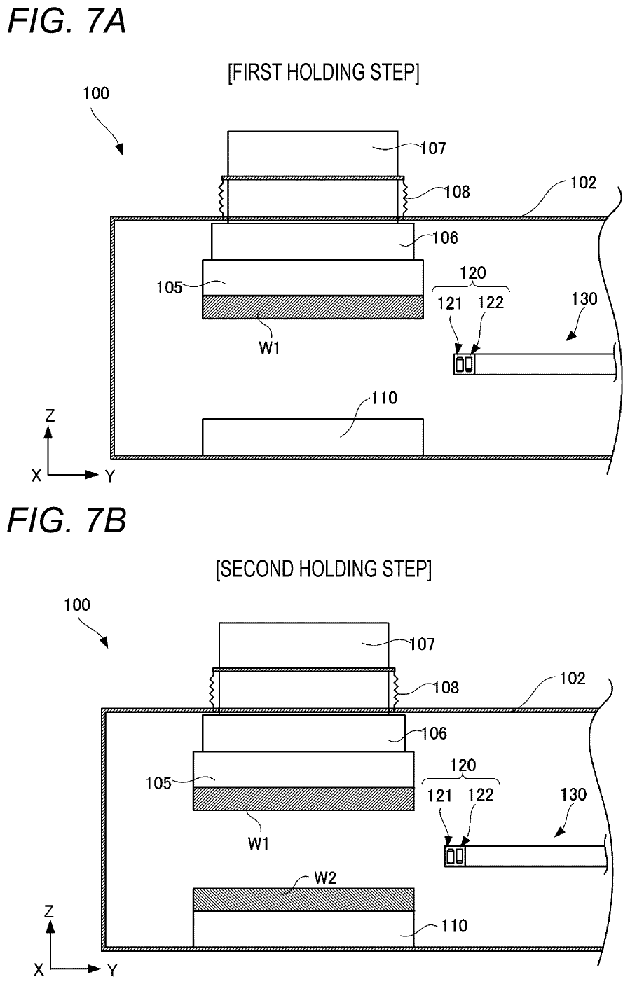

In the first holding step S10, as illustrated in FIG. 7A, the controller 210 causes the first holding portion 105 to hold the first substrate W1. That is, the controller 210 causes the carrying unit 50 to carry the first substrate W1 accommodated in the cassette C1 to the first holding portion 105, directs the bonding surface with the second substrate W2 downward, and causes the first holding portion 105 to hold the surface facing the bonding surface.

Similarly, in the second holding step S11, as illustrated in FIG. 7B, the controller 210 causes the second holding portion 110 to hold the second substrate W2. That is, the controller 210 causes the carrying unit 50 to carry the second substrate W2 accommodated in the cassette C1 to the second holding portion 110, directs the bonding surface with the first substrate W1 downward, and causes the second holding portion 110 to hold the surface facing the bonding surface. The order of the first holding step S10 and the second holding step S11 may be reversed.

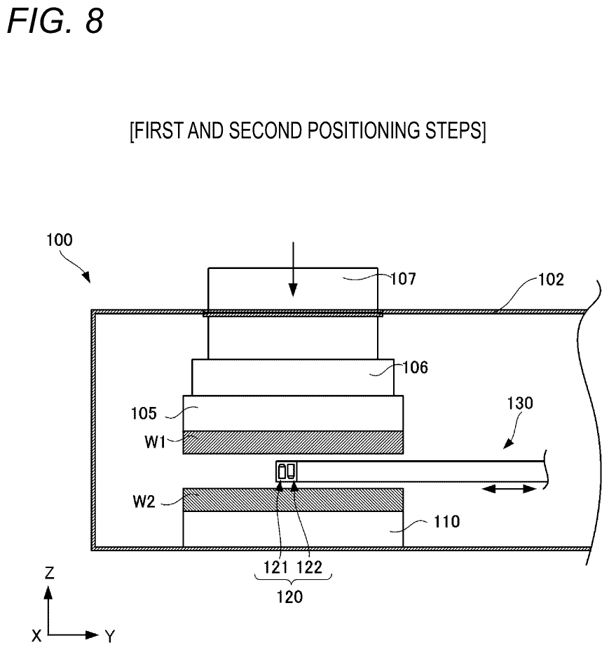

In the first positioning step S12, the controller 210 moves the first imaging portion 121 of the imaging unit 120 to, for example, an imaging position corresponding to the position where the first alignment mark M1 of the first substrate W1 is formed using the moving unit 130, and focuses the first wide-area objective lens 121a on the first substrate W1 (see FIG. 8). The controller 210 controls the lifting mechanism (not illustrated) to lower the first holding portion 105 to a predetermined height position, thereby bringing the first holding portion 105 closer to the second holding portion 110. In this way, when the first imaging portion 121 is located at a predetermined position, the first wide-area objective lens 121a of the first imaging portion 121 is used to capture an image of the first substrate W1.

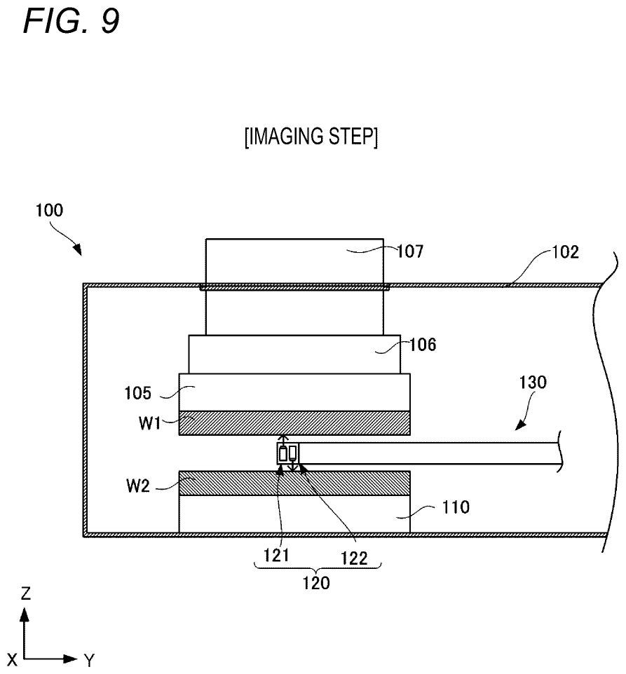

In the first imaging step S13, as illustrated in FIG. 9, the controller 210 captures an image of the first substrate W1 including the first alignment mark M1 using the first wide-area objective lens 121a, based on the imaging position moved to in the first positioning step S12. The imaging result is output to the control unit 200.

Similarly, in the second positioning step S14, for example, the controller 210 moves the second imaging unit 122 of the imaging unit 120 to an imaging position corresponding to the position where the second alignment mark M2 of the second substrate W2 is formed, and focuses the second wide-area objective lens 122a on the second substrate W2. In the second positioning step S14, the controller 210 may adjust the distance between the first holding portion 105 and the second holding portion 110 by controlling the lifting mechanism. In this way, when the second imaging unit 122 is positioned at a predetermined position, the second wide-area objective lens 122a of the second imaging unit 122 is used to capture an image of the second substrate W2.

In the second imaging step S15, the controller 210 captures an image of the second substrate W2 including the second alignment mark M2 using the second wide-area objective lens 122a, based on the imaging position moved to in the second positioning step S14. The imaging result is output to the control unit 200.

Since both the first imaging portion 121 and the second imaging portion 122 are attached to the moving unit 130 and are integrally movable, the first positioning step S12 and the first imaging step S13, and the second positioning step S14 and the second imaging step S15 may be simultaneously executed. By executing the steps simultaneously, it is possible to shorten the time until the first substrate W1 and the second substrate W2 are bonded. In the embodiment, an example has been described in which an image of the second substrate W2 is captured after an image of the first substrate W1 is captured, but the order may be reversed. That is, the order of the first positioning step S12 and the first imaging step S13 and the second positioning step S14 and the second imaging step S15 may be reversed.

In the pre-alignment step S16, the controller 210 adjusts the horizontal position of the first holding portion 105 by controlling the adjustment unit 106, based on the imaging result of the first substrate W1 using the first wide-area objective lens 121a of the first imaging portion 121 and the imaging result of the second substrate W2 using the second wide-area objective lens 122a of the second imaging portion 122. For example, the controller 210 controls the adjustment unit 106 to adjust the horizontal position of the first holding portion 105, thereby matching the shape of the first alignment mark M1 with the shape of the second alignment mark M2. The “match” of the shapes in the pre-alignment step S16 does not necessarily mean a perfect match, and may have a predetermined misalignment amount in advance. Then, the first positioning step S12 to the second imaging step S15 may be repeatedly executed until the predetermined misalignment amount falls within a threshold α.

In the third imaging step S17, the controller 210 uses the moving unit 130 to move, for example, the imaging unit 120 to the position where an image is captured using the first wide-area objective lens 121a described above, focuses the first local objective lens 121b on the first substrate W1, and captures an image of the first alignment mark M1. The imaging result is output to the control unit 200.

Similarly, in the fourth imaging step S18, the controller 210 using the moving unit 130 to move, for example, the imaging unit 120 to the position where an image is captured using the second wide-area objective lens 122a described above, focuses the second local objective lens 122b on the second substrate W2, and captures an image of the second alignment mark M2. The imaging result is output to the control unit 200.

Since both the first imaging portion 121 and the second imaging portion 122 are attached to the moving unit 130 and are integrally movable, the fourth imaging step S18 and the third imaging step S17 may be simultaneously executed. By executing the steps simultaneously, it is possible to shorten the time until the first substrate W1 and the second substrate W2 are bonded. The order of the third imaging step S17 and the fourth imaging step S18 may be reversed.

In the fine alignment step S19, the controller 210 adjusts the horizontal position of the first holding portion 105 by controlling the adjustment unit 106, based on the imaging result of the first substrate W1 using the first local objective lens 121b of the first imaging portion 121 and the imaging result of the second substrate W2 using the second local objective lens 122b of the second imaging portion 122. For example, the controller 210 controls the adjustment unit 106 to adjust the horizontal position of the first holding portion 105, thereby matching the shape of the first alignment mark M1 with the shape of the second alignment mark M2. The “match” of the shapes in the fine alignment step S19 does not necessarily mean a perfect match, and may have a predetermined misalignment amount in advance. A threshold β for the predetermined misalignment amount is smaller than the threshold α for the misalignment amount in the pre-alignment step S16. The threshold β is a predetermined value that allows the misalignment between the substrates. This is because the process of the fine alignment step S19 is a final alignment process of the first alignment mark M1 and the second alignment mark M2. The controller 210 repeatedly executes the third imaging step S17 and the fourth imaging step S18 until the misalignment amount falls within the threshold β.

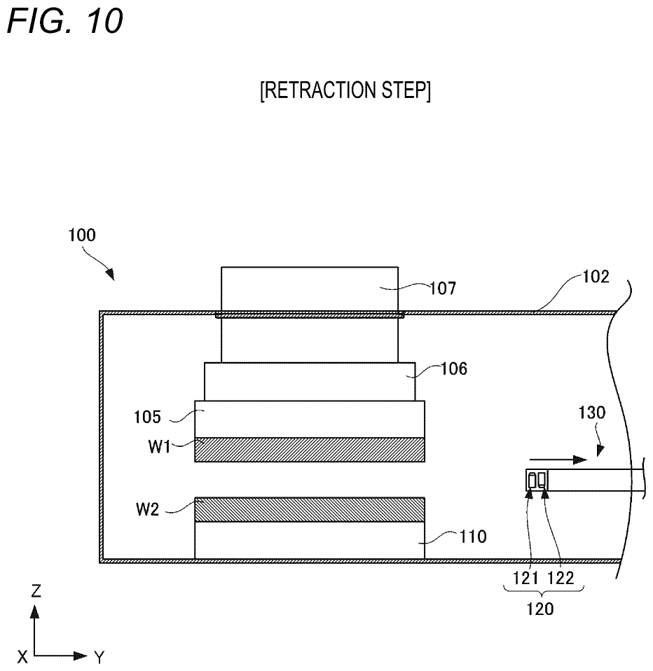

In the retraction step S20, as illustrated in FIG. 10, the controller 210 moves the moving unit 130 to the predetermined retracted position that is a position deviated from the imaging position between the first holding portion 105 and the second holding portion 110. In the example illustrated in FIG. 10, the moving unit 130 is retracted from the imaging position by moving the moving unit 130 in the Y-axis direction.

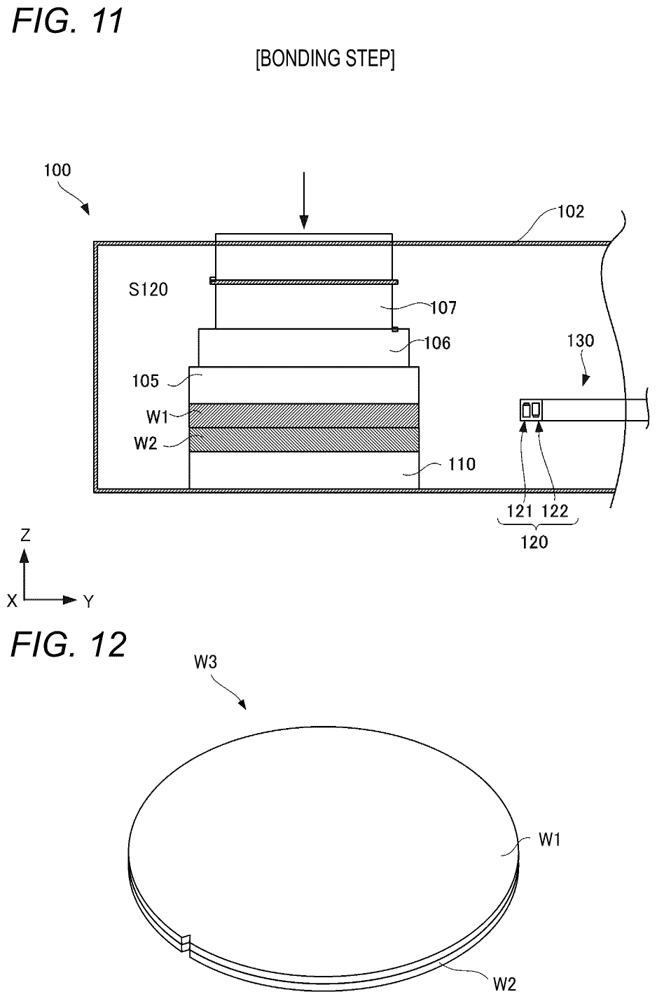

In the bonding step S21, as illustrated in FIG. 11, the controller 210 controls the lifting mechanism to press the first holding portion 105 together with the shaft 107 in a direction in which the first holding portion 105 approaches the second holding portion 110. As a result, the first substrate W1 and the second substrate W2 gradually approach each other and are bonded together. Before executing the bonding step S21, the controller 210 executes a decompression process to reduce the pressure in the internal space of the chamber 102. As a result, the inside of the chamber 102 is put into a high vacuum state. In the high vacuum state, the bonding step S21 is performed. When the bonding step S21 is executed, a bonded substrate W3 in which the first substrate W1 and the second substrate W2 are bonded together is produced.

By such a series of processes, hydrogen atoms of OH groups formed on the front surface of the first substrate W1 form a hydrogen bond with oxygen atoms of OH groups formed on the front surface of the second substrate W2. Similarly, hydrogen atoms of OH groups formed on the front surface of the second substrate W2 form a hydrogen bond with the oxygen atom of the OH group formed on the front surface side of the first substrate W1. By these hydrogen bonds, the first substrate W1 and the second substrate W2 are attracted to each other and temporarily bonded.

Thereafter, the controller 210 releases the atmosphere in the chamber 102, releases the suction holding of the first substrate W1 by the first holding portion 105, releases the suction holding of the second substrate W2 by the second holding portion 110, and carries the produced bonded substrate W3 to the cassette C2 by the carrying unit 50 such that the bonded substrate W3 is accommodated in the cassette C2.

Then, the bonded substrate W3 temporarily bonded in this manner is subjected to a heating treatment by an annealing treatment apparatus (not illustrated). On the bonding surfaces of the first substrate W1 and the second substrate W2 bonded together, water (H₂O is lost from the OH groups formed on the front surfaces of the first substrate W1 and the second substrate W2, and thus covalent bonding via an oxygen bond is formed. As a result, the degree of bonding between the substrates is further improved, and the temporary bonding becomes complete bonding. The substrates bonded in this manner become a bonded substrate W3 as illustrated in FIG. 12, for example.

Although the embodiments of the present disclosure have been described above with reference to the accompanying drawings, it is needless to say that the present disclosure is not limited to the embodiments. It is obvious that those skilled in the art may come up with various changes or modifications within the scope of the claims, and it is understood that these naturally fall within the technical scope of the present disclosure. In addition, components in the embodiments described above may be freely combined without departing from the gist of the disclosure.

For example, although one alignment mark is formed on the first substrate W1 and one alignment mark is formed on the second substrate W2 in the embodiment described above, a plurality of alignment marks may be formed on each of the first substrate W1 and the second substrate W2. For example, a plurality of alignment marks are formed at the same positions on the first substrate W1 and the second substrate W2. In such a case, as described above, when the first imaging portion 121 and the second imaging portion 122 are disposed in parallel on the same plane, even if images of corresponding different alignment marks M are captured, the accuracy of alignment can be improved.

In the embodiment described above, in order to capture an image of the alignment mark M by the imaging unit 120, the imaging unit 120 is moved to a predetermined imaging position by moving the moving unit 130 to which the imaging unit 120 is attached, but the imaging unit 120 may be located at the predetermined imaging position by relatively moving the first holding portion 105 and the second holding portion 110 holding the substrate W.

The substrate bonding method described in the above embodiment can be implemented by executing a control program prepared in advance by a computer. The control program is recorded in a computer-readable storage medium and executed by being read from the storage medium. The control program may be provided in a form stored in a non-transitory storage medium such as a flash memory, or may be provided via a network such as the Internet. The computer that executes the control program may be included in a processing device, may be included in an electronic device such as a smartphone, a tablet terminal, or a personal computer capable of communicating with the processing device, or may be included in a server device capable of communicating with the processing device and the electronic device.

The present specification describes at least the following matters. Corresponding components and the like in the embodiment described above are shown in parentheses, and the present disclosure is not limited thereto.
(1) A bonding apparatus (bonding apparatus 1) for bonding a first substrate (first substrate W1) and a second substrate (second substrate W2), the bonding apparatus including:
a first holding portion (first holding portion 105) configured to hold the first substrate;
a second holding portion (second holding portion 110) disposed to face the first holding portion and configured to hold the second substrate to be bonded to the first substrate;
an imaging unit (imaging unit 120) including a first imaging portion (first imaging portion 121) including a first objective lens (first wide-area objective lens 121a) that captures an image of a first alignment mark (first alignment mark M1) formed on the first substrate held by the first holding portion, and a second imaging portion (second imaging portion 122) including a second objective lens (second wide-area objective lens 122a) that captures an image of a second alignment mark (second alignment mark M2) formed on the second substrate held by the second holding portion; and
a moving unit (moving unit 130) configured to relatively move the imaging unit, the first holding portion, and the second holding portion in a region between the first holding portion and the second holding portion, in which
in the imaging unit, an optical axis of the first objective lens and an optical axis of the second objective lens are not on the same straight line.

According to (1), since the optical axis of the first objective lens and the optical axis of the second objective lens are not on the same straight line, a distance between the first holding portion that holds the first substrate and the second holding portion that holds the second substrate disposed to face the first holding portion is shorter than in a configuration in which, for example, the optical axis of the first objective lens and the optical axis of the second objective lens are on the same straight line. Therefore, a distance between the first substrate and the second substrate held by the respective holding portions is also shortened, and as a result, it is possible to prevent misalignment between the substrates when the bonded substrate is produced. In addition, since the distance between the first substrate and the second substrate can be shortened as described above, the time until the substrates approach each other can also be shortened, and thus the productivity of the bonded substrate can be improved.
(2) The bonding apparatus according to (1), in which
the first imaging portion further includes a third objective lens (first local objective lens 121b) having a magnification higher than that of the first objective lens,
the second imaging portion further includes a fourth objective lens (second local objective lens 122b) having a magnification higher than that of the second objective lens, and
an optical axis of the third objective lens and an optical axis of the fourth objective lens are not on a same straight line.

According to (2), since the optical axis of the third objective lens, which has a magnification relatively higher than that of the first objective lens, and the optical axis of the fourth objective lens, which has a magnification relatively higher than that of the second objective lens, are not on the same straight line, as compared with a configuration in which the optical axis of the third objective lens and the optical axis of the fourth objective lens are on the same straight line, the distance between the first substrate and the second substrate held by the respective holding portions can be shortened, and as a result, it is possible to prevent misalignment between the substrates when the bonded substrate is produced.
(3) The bonding apparatus according to (2), in which
optical axes of the first objective lens, the second objective lens, the third objective lens, and the fourth objective lens are not on a same straight line.

According to (3), since the optical axes of the first objective lens, the second objective lens, the third objective lens, and the fourth objective lens are not on the same straight line, for example, as compared with a case where any of the objective lenses is disposed on the same straight line as the other objective lenses, the distance between the first substrate and the second substrate held by the respective holding portions can be shortened, and as a result, it is possible to prevent misalignment between the substrates when the bonded substrate is produced.
(4) The bonding apparatus according to (3), in which
the first objective lens, the second objective lens, the third objective lens, and the fourth objective lens are disposed in the shape of field character grid in a plan view.

According to (4), the first objective lens, the second objective lens, the third objective lens, and the fourth objective lens are disposed in the shape of field character grid in a plan view, and the optical axes of the respective objective lenses do not overlap on the same straight line. Therefore, for example, as compared with a case where any of the objective lenses is disposed on the same straight line as the other objective lenses, the distance between the first substrate and the second substrate held by the respective holding portions can be shortened, and as a result, it is possible to prevent misalignment between the substrates when the bonded substrate is produced.
(5) The bonding apparatus according to (3), in which
the first objective lens, the second objective lens, the third objective lens, and the fourth objective lens are disposed in an overlapping manner such that two objective lenses are visible when viewed from a moving direction (Y-axis direction, X-axis direction) of the moving unit, and are disposed in an overlapping manner such that two objective lenses are visible when viewed from a direction (X-axis direction, Y-axis direction) orthogonal to the moving direction on a same plane.

According to (5), with such an arrangement, the first objective lens, the second objective lens, the third objective lens, and the fourth objective lens are disposed at four locations at equal intervals in a horizontal plane in the X-axis direction and the Y-axis direction. As a result, since the optical axes of the respective objective lenses do not overlap on the same straight line, for example, as compared with a case where any of the objective lenses is disposed on the same straight line as the other objective lenses, the distance between the first substrate and the second substrate held by the respective holding portions can be shortened, and as a result, it is possible to prevent misalignment between the substrates when the bonded substrate is produced.
(6) A bonding method for bonding a first substrate (first substrate W1) and a second substrate (second substrate W2), the bonding method including:
a first holding step (first holding step S10) of holding the first substrate by a first holding portion (first holding portion 105);
a second holding step (second holding step S11) of holding the second substrate by a second holding portion (second holding portion 110) disposed to face the first holding portion;
a first positioning step (first positioning step S12) of positioning an imaging unit (imaging unit 120) in a region between the first holding portion and the second holding portion in order to capture an image of a first alignment mark with a first objective lens, the imaging unit including a first imaging portion (first imaging portion 121) including the first objective lens (first wide-area objective lens 121a) that captures an image of the first alignment mark (first alignment mark M1) formed on the first substrate held by the first holding portion, and a second imaging portion (second imaging portion 122) including a second objective lens (second wide-area objective lens 122a) that captures an image of a second alignment mark (second alignment mark M2) formed on the second substrate held by the second holding portion and that has an optical axis not disposed on a same straight line as an optical axis of the first objective lens;
a first imaging step (first imaging step S13) of capturing an image of the first alignment mark using the imaging unit after the first positioning step;
a second positioning step (second positioning step S14) of positioning the imaging unit in the region between the first holding portion and the second holding portion in order to capture an image of the second alignment mark with the second objective lens;
a second imaging step (second imaging step S15) of capturing an image of the second alignment mark using the imaging unit after the second positioning step;
a retraction step (retraction step S20) of retracting the imaging unit located in the region between the first holding portion and the second holding portion; and
a bonding step (bonding step S21) of bonding the first substrate and the second substrate after the retraction step.

According to (6), the distance between the first substrate and the second substrate held by the respective holding portions is shortened, and as a result, it is possible to prevent misalignment between the substrates when the bonded substrate is produced. In addition, since the distance between the first substrate and the second substrate can be shortened as described above, the time until the substrates approach each other can be shortened, and thus the productivity of the bonded substrate can be improved.
(7) The bonding method according to (6), in which
the first positioning step and the first imaging step, and the second positioning step and the second imaging step are simultaneously performed.

According to (7), for example, as compared with a case where the first positioning step and the first imaging step, and the second positioning step and the second imaging step are not simultaneously performed, the time required for producing a bonded substrate can be shortened, and as a result, the productivity of the bonded substrate can be improved.

1. A bonding apparatus for bonding a first substrate and a second substrate, the bonding apparatus comprising:
a first holding portion configured to hold the first substrate;
a second holding portion disposed to face the first holding portion and configured to hold the second substrate to be bonded to the first substrate;
an imaging unit including a first imaging portion including a first objective lens that captures an image of a first alignment mark formed on the first substrate held by the first holding portion, and a second imaging portion including a second objective lens that captures an image of a second alignment mark formed on the second substrate held by the second holding portion; and
a moving unit configured to relatively move the imaging unit, the first holding portion, and the second holding portion in a region between the first holding portion and the second holding portion, wherein
in the imaging unit, an optical axis of the first objective lens and an optical axis of the second objective lens are not on a same straight line.

2. The bonding apparatus according to claim 1, wherein
the first imaging portion further includes a third objective lens having a magnification higher than that of the first objective lens,
the second imaging portion further includes a fourth objective lens having a magnification higher than that of the second objective lens, and
an optical axis of the third objective lens and an optical axis of the fourth objective lens are not on a same straight line.

3. The bonding apparatus according to claim 2, wherein
optical axes of the first objective lens, the second objective lens, the third objective lens, and the fourth objective lens are not on a same straight line.

4. The bonding apparatus according to claim 3, wherein
the first objective lens, the second objective lens, the third objective lens, and the fourth objective lens are disposed in a shape of field character grid in a plan view.

5. The bonding apparatus according to claim 3, wherein
the first objective lens, the second objective lens, the third objective lens, and the fourth objective lens are disposed in an overlapping manner such that two objective lenses are visible when viewed from a moving direction of the moving unit, and are disposed in an overlapping manner such that two objective lenses are visible when viewed from a direction orthogonal to the moving direction on a same plane.

6. A bonding method for bonding a first substrate and a second substrate, the bonding method comprising:
first holding the first substrate by a first holding portion;
second holding the second substrate by a second holding portion disposed to face the first holding portion;
first positioning an imaging unit in a region between the first holding portion and the second holding portion in order to capture an image of a first alignment mark with a first objective lens, the imaging unit including a first imaging portion including the first objective lens that captures an image of the first alignment mark formed on the first substrate held by the first holding portion, and a second imaging portion including a second objective lens that captures an image of a second alignment mark formed on the second substrate held by the second holding portion and that has an optical axis not disposed on a same straight line as an optical axis of the first objective lens;
first capturing an image of the first alignment mark using the imaging unit after the first positioning;
second positioning the imaging unit in the region between the first holding portion and the second holding portion in order to capture an image of the second alignment mark with the second objective lens;
second capturing an image of the second alignment mark using the imaging unit after the second positioning;
retracting the imaging unit located in the region between the first holding portion and the second holding portion; and
bonding the first substrate and the second substrate after the retracting.

7. The bonding method according to claim 6, wherein
the first positioning and the first capturing, and the second positioning and the second capturing are simultaneously performed.
